(19) United States
(12) Patent Application Publication
(10) Pub. No.: US 2026/0023136 A1
(43) Pub. Date: Jan. 22, 2026

(54) INTEGRATED CIRCUIT PACKAGING WITH CONDUCTIVE FILM

(71) Applicant: Allegro MicroSystems, LLC, Manchester, NH (US)

(72) Inventors: Weidong Wang, Westford, MA (US); David Youm, Malden, MA (US); Natasha Healey, Manchester, NH (US)

(73) Assignee: Allegro MicroSystems, LLC, Manchester, NH (US)

(21) Appl. No.: 18/776,663

(22) Filed: Jul. 18, 2024

(51) Int. Cl. H01L 23/00; G01R 33/00; H01L 23/495

(52) U.S. Cl. CPC H01L 24/32; G01R 33/0047; G01R 33/0052; H01L 23/49541; H01L 24/13; H01L 24/16; H01L 24/73; H01L 24/83; H01L 2224/13147; H01L 2224/16245; H01L 2224/3201; H01L 2224/32245; H01L 2224/73204; H01L 2224/83203; H01L 2924/182

(57) ABSTRACT

A current sensor integrated circuit (IC) package is flip-chip bonded using a conductive film to connect the IC circuit bond pads to the lead frame. A conductive film is positioned between the die surface of a semiconductor die and at least one signal lead of the lead frame. The conductive film is conductive in a first direction between the die and the signal lead and nonconductive in other directions. The conductive film is further configured to control a gap height between the die and the lead frame to reduce die tilt, thus improving the sensitivity and performance consistency of the package.

### BACKGROUND

During the manufacture of some current sensor integrated circuit (IC) packages, a semiconductor die carrying the sensing elements is disposed over a lead frame that includes a primary conductor and a number of signal leads. During assembly, electrical connections are made between pads on the semiconductor die and the lead frame, typically with wire bonds, solder balls or other conductive materials. The placement of the die over a lead frame, and potentially an insulation material, creates a gap between the die, the primary conductor and the signal leads. In a flip-chip configuration using solder balls, the solder balls must be deposited on the die, and subsequently heated after placement of the die onto lead frame to allow an electrical connection to form with the lead frame. The heating and cooling, or so called reflow process, can lead to inconsistent connections.

Additionally, a gap height differential may occur when, for example, the gap between the semiconductor die and the primary conductor, including an insulation layer, differs from the gap between the semiconductor die and the signal leads. The differing gap heights may be a result of inconsistent or collapsed solder bumps, isolation tape thickness, and/or a combination of both. Die tilt may cause partial discharge failures on voltage isolation testing as well as sensitivity drift.

### SUMMARY

Aspects of the present disclosure relate to current sensor integrated circuit (IC) packages including flip-chip bonding using a conductive film to connect the IC circuit bond pads to the lead frame. A conductive film may be positioned between the die surface of a semiconductor die and at least one signal lead of the lead frame. The conductive film may be conductive in a first direction between the die and the signal lead and be nonconductive in other directions. The conductive film may be further configured to control a gap height between the die and the lead frame to reduce die tilt, thus improving the sensitivity and performance consistency of the package.

According to one aspect, an IC package may include a lead frame comprising a primary conductor and signal leads. The lead frame may have a lead frame surface. A semiconductor die may have a die surface adjacent to the lead frame surface. The semiconductor die may comprise a magnetic field sensing element supported by the semiconductor die. The magnetic field sensing element may be configured to sense a magnetic field associated with a current through the primary conductor and generate an output signal indicative of the current. A conductive film may be located between the die surface of the semiconductor die and at least one signal lead. The conductive film may be conductive in a first direction extending from the die surface to the at least one signal lead and nonconductive in a second direction which is perpendicular to the first direction.

The IC package may further include, alone or in combination, one or more of the following features. The conductive film may comprise an anisotropic conductive film (ACF). The semiconductor die may be bonded to the lead frame in a flip-chip arrangement. The conductive film may be configured to prevent a tilt of the semiconductor die relative to the lead frame. An insulation structure may be between the semiconductor die and the primary conductor. The conductive film may have a thickness substantially equal to an insulation thickness of the insulation structure. The insulation structure may include a polymer film. The conductive film may be configured to control a gap height between the semiconductor die and the lead frame. The semiconductor die may include one or more bumps coupling the semiconductor die to the conductive film. The one or more bumps may include copper bumps. A molding may encapsulate the semiconductor die and at least a portion of the lead frame. The first direction may be orthogonal to the die surface.

According to another aspect, a method of manufacturing an IC package may include providing a lead frame comprising a primary conductor and signal leads. The lead frame may have a lead frame surface. A semiconductor die may be positioned having a die surface adjacent to the lead frame surface. The semiconductor die may comprise a magnetic field sensing element supported by the semiconductor die. The magnetic field sensing element may be configured to sense a magnetic field associated with a current through the primary conductor and generate an output signal indicative of the current. A conductive film may be positioned between the die surface of the semiconductor die and at least one signal lead. The conductive film may be conductive in a first direction extending from the die surface to the at least one signal lead and nonconductive in a second direction which is perpendicular to the first direction.

The method may further include, alone or in combination, one or more of the following features. The conductive film may comprise an anisotropic conductive film (ACF). The semiconductor die may be bonded to the lead frame in a flip-chip arrangement. The conductive film may be configured to prevent a tilt of the semiconductor die relative to the lead frame. An insulation structure may be between the semiconductor die and the primary conductor. The conductive film may have a thickness substantially equal to an insulation thickness of the insulation structure. The insulation structure may include a polymer film. The conductive film may be configured to control a gap height between the semiconductor die and the lead frame. The semiconductor die may include one or more bumps coupling the semiconductor die to the conductive film. The one or more bumps may include copper bumps. A molding may encapsulate the semiconductor die and at least a portion of the lead frame. The first direction may be orthogonal to the die surface.

According to another aspect, an IC package may include a lead frame comprising a primary conductor and signal leads. The lead frame may have a lead frame surface. A semiconductor die may have a die surface adjacent to the lead frame surface. The semiconductor die may comprise a magnetic field sensing element supported by the semiconductor die. The magnetic field sensing element may be configured to sense a magnetic field associated with a current through the primary conductor and generate an output signal indicative of the current. An anisotropic conductive film may be heat-pressed to one or both of the die surface and at least one signal lead. The anisotropic conductive film may be conductive in a first direction extending from the die surface to the at least one signal lead and nonconductive in a second direction which is perpendicular to the first direction. The anisotropic conductive film may be configured to control a gap height between the semiconductor die and the at least one signal lead.

### BRIEF DESCRIPTION OF THE DRAWINGS

The foregoing features of the disclosure, as well as the disclosure itself may be more fully understood from the following detailed description of the drawings. The drawings aid in explaining and understanding the disclosed technology. Since it is often impractical or impossible to illustrate and describe every possible embodiment, the provided figures depict one or more exemplary embodiments. Accordingly, the figures are not intended to limit the scope of the invention. Like numbers in the figures denote like elements.

FIG. 1 is a partially transparent top view of an IC package including a conductive film, according to aspects of the disclosure.

FIG. 2A is a partially transparent side view of the IC package in FIG. 1, according to aspects of the disclosure.

FIG. 2B is an expanded view of a portion of the IC package of FIG. 2A, according to aspects of the disclosure.

FIG. 3 is a partially transparent reverse view of the IC package in FIG. 1, according to aspects of the disclosure.

### DETAILED DESCRIPTION

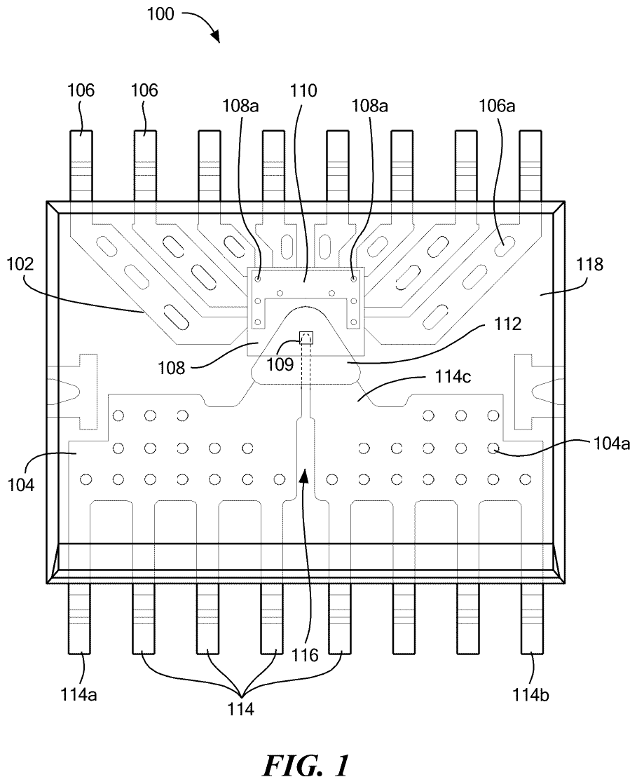

Referring to the various views of FIGS. 1-3, a current sensor integrated circuit (IC) package 100 includes a lead frame 102 with a primary conductor 104 and a plurality of signal leads, collectively labeled 106. It will be appreciated by those of ordinary skill in the art that although the lead frame 102 is shown to have eight signal leads, other numbers, dimensions, spacing, and configurations of leads are possible.

A semiconductor die 108 may include a first magnetic field sensing element 109 for sensing a magnetic field associated with a current through the primary conductor 104 to generate a first output signal indicative of the current for coupling to a signal lead 106. With this arrangement, the semiconductor die 108 is arranged in a so-called flip-chip configuration in which the sensing element 109 is supported by a die surface proximal to the lead frame 102.

According to one aspect, the magnetic field sensing element 109 can be a single element or can include more than one element, such as a dual Hall element or a quad Hall element or one or more magnetoresistance elements as are sometimes arranged in a bridge configuration and as may be used to implement differential magnetic field sensing.

The primary conductor 104 may have various shapes and dimensions to accommodate a range of current levels sought to be detected by the current sensor IC package 100 and the desired package footprint. In general, the primary conductor 104 may include an input portion 114a, an output portion 114b, and a current path region 114c between the input and output portions. In use, a current flow may be established through the primary conductor 104 between the input and output portions 114a, 114b.

The input and output portions 114a, 114b of the primary conductor 104 may have respective terminal ends in the form of leads, collectively labeled 114, configured for electrical connection to a printed circuit board (PCB) or other substrate on which the current sensor IC package 100 may be mounted. The leads 114 of the primary conductor 104 and signal leads 106 can take various forms, such as the illustrated leads that are bent to facilitate surface mount solder connection to a PCB or other substrate. The current sensor IC package 100 may be considered an SOIC (Small Outline Integrated Circuit) package. In other embodiments, package types include QFN (Quad-Flat No-Leads), DFN (Dual-Flat No-Leads), and the like.

The current path region 114c of the primary conductor 104 can have various shapes and other characteristics. Here, the current path region 114c is curved in a “horseshoe” shape to form a notch 116. Placement of the magnetic field sensing element 109 relative to the curved, current path region 114c and notch 116 may concentrate the magnetic field generated by current through the primary conductor 114 on the sensing elements. It will be appreciated that other shapes, dimensions, notches, and sensing element placement can be implemented to achieve concentration of the magnetic field.

According to one aspect, the magnetic field sensing element 109 can include one or more elements that are substantially vertically aligned with a first side of the notch 116 and one or more elements that are substantially vertically aligned with a second side of the notch 116. As current flows through the primary conductor 104, having a magnetic field sensing element positioned to the sides of the conductor (rather than directly over or under the conductor) results in magnetic field with components perpendicular to the semiconductor die 108 such that the sensing elements may be planar Hall effect elements. In other aspects, the magnetic field sensing element or elements 109 may be positioned directly over the primary conductor 104 to sense magnetic field components parallel to the surface of semiconductor die 108, in which case sensing elements such as a vertical Hall element, a GMR, TMR, or AMR element may be used.

The lead frame 102 may comprise any suitable conductive material, such as copper or copper alloy or Aluminum, and its features can be formed by various methods such as stamping or etching.

In applications in which the primary conductor 104 can be at a relatively high voltage, safety specifications may require that a certain electrical isolation be maintained between the primary conductor 104 and other parts of the circuitry (e.g., signal leads 106 coupled to an external system to which a sensor output signal is communicated). According to one aspect of the disclosure, electrical isolation between the primary conductor 104 and the flip-chip semiconductor die 108 may be achieved with various mechanisms, such as with an insulation structure 112 disposed, at least, between the primary conductor 104 and the proximal surface of the semiconductor die 108. Alternatively, the insulation structure may not be included if the package does not require it, for example, when the primary conductor is at a low voltage.

The insulation structure 112 may include an organic polymer such as polyimide, or an oxide insulating material like silicon dioxide in the form of a glass sheet, silicone or ceramic. For example, the insulation structure 112 may be a polymer film, as may be provided in the form of a polyimide or Kapton® tape, as non-limiting examples. The insulation structure 112 may include an adhesive layer, in which case the polymer film and the adhesive layer may be provided as a tape with which the insulating layers are attached to the lead frame 102 and such an adhesive layer can itself provide insulation.

According to one aspect, the flip-chip configured semiconductor die 108 may be electrically and mechanically coupled to the signal leads 106, by a conductive film, such as anisotropic conductive film (ACF) 110. The ACF 110 may electrically connect bond pads 108a of the semiconductor die 108 to the signal leads 106. The ACF may include a thermal-set film filled with conductive particles that allow electric conductivity only in a vertical direction. Accordingly, the ACF film may provide electric insulation in lateral (or non-vertical) directions. According to one aspect, the conductive film may be a paste, such as anisotropic conductive paste (ACP).

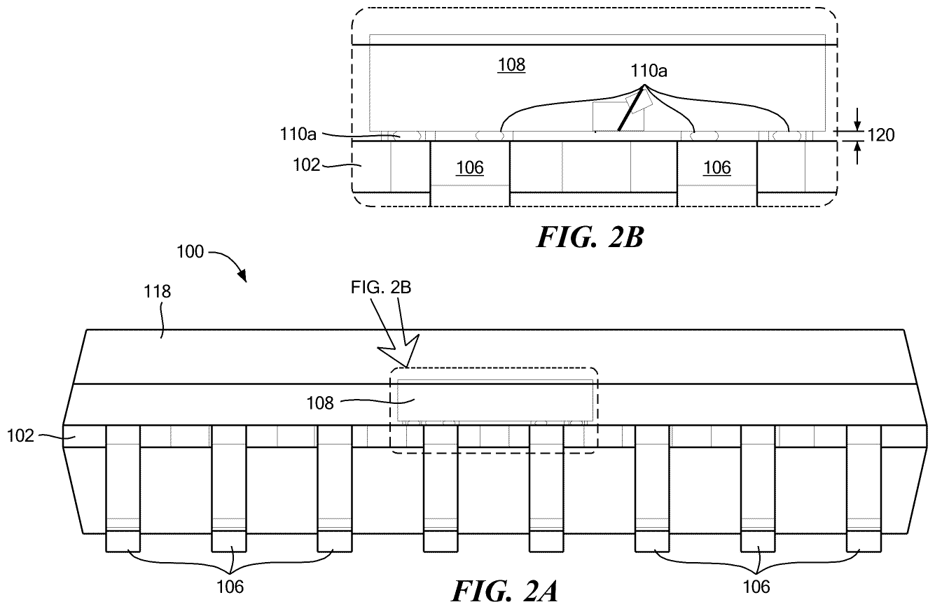

According to one aspect, the ACF 110 may be mounted, using a lamination process or the like, on either the semiconductor die 108 or on the lead frame 102. With heat applied (e.g. heat-pressed) to the assembly, the die 108 and/or lead frame 102 may be compressed for a time to allow the film to bond to the respective surfaces. During the mounting process, electrically conductive particles 110a (FIG. 2B) in the ACF 110 may become fixed between the conductive pads 108a of the die 108 and the signal leads 106 to form an electrical connection. Non-conductive portions of the ACF 110 may insulate the conductive particles 110a preventing conductivity in non-vertical directions.

The ACF 110 may provide a mechanism to control the gap height between the die 108 and the lead frame 102 as well as reduce die tilt with respect to the lead frame. The compressibility of the ACF 110 during mounting and assembly allows for precise control of the distance between the die 108 and the lead frame 102. As used herein, a uniform gap height may refer to a gap height, for example and without limitation, between about 0.0381 mm and 0.0635 mm, between the lead frame 102 and the semiconductor die 108 that is substantially the same at the primary conductor 104 as it is at the signal leads 106.

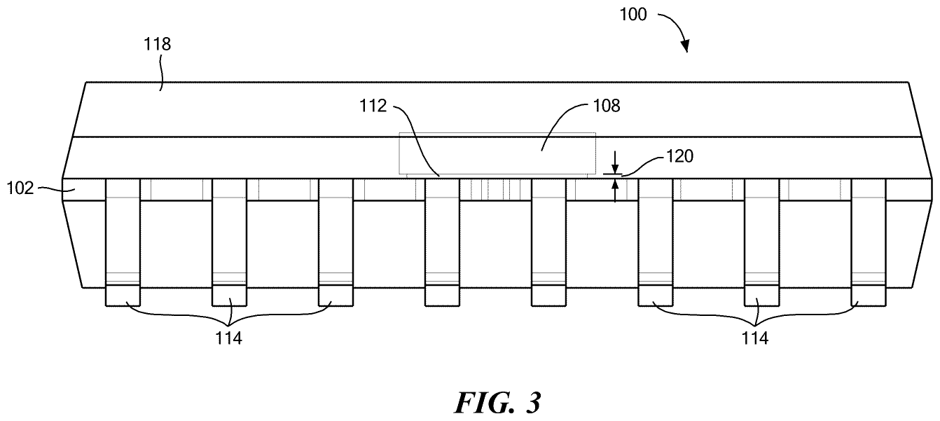

As shown in FIG. 2B, the ACF 110, including conductive particles 110a, is compressed between the die 108 and the signal leads 106 such that a uniform gap height, labelled as 120, is achieved across the package 100. The uniform gap height 120 (and the reduced tilt of the die 108) provides increased consistency in the connections between the die 108 and the signal leads 106. According to one aspect, as shown in FIG. 3, the use of the insulation structure 112 may further support the formation of the uniform gap height 120 between the die 108 and the primary conductor 104 of the lead frame 102.

According to one aspect, bonding between the die 108 and the lead frame 102 may be enhanced both mechanically and electrically using copper bumps or pillars, as non-limiting examples, formed on the bond pads 108a of the semiconductor die 108. One or more bumps may be so-called “dummy” bumps, in that they provide only mechanical attachment and/or stability rather than both mechanical and electrical coupling. In the case of a dummy bump, the bond pad to which the dummy bump is connected is not electrically connected to the circuitry on the die 108. Such electrical isolation may be achieved with materials including, but not limited to an oxide, a nitride, or a polymer isolation layer or combinations thereof.

The current sensor IC package 100 may include insulating material in the form of a mold material 118 configured to encapsulate the semiconductor die 108 and portions of the lead frame 102. The mold material 118 is shown to illustrate elements encapsulated within the IC package 100. Various materials can be used to form the mold material 118, including, but not limited to a plastic material.

Portions of the lead frame 102 may include features configured to enhance adhesion of the mold material 118 to the lead frame 102, thereby serving as a “locking mechanism” to secure parts of the IC package 100 together. Here, holes 106a through the signal leads 106, and holes 104a through the primary conductor 104 can provide such a locking mechanism. The entire structure, excluding terminal ends of the signal leads 106 and primary leads 114, can be overmolded with the mold material 118 in a mold process step, following which terminal ends of the primary conductor leads 114 and the signal leads 106 can be bent, as shown. The mold material 118 may be formed by a transfer mold process, which may include one or more mold process steps.

The detailed description set forth above, in connection with the appended drawings, is intended as a description of various configurations and is not intended to represent the only configurations in which the concepts described herein may be practiced. The detailed description includes specific details for providing a thorough understanding of the various concepts. It will be apparent to those skilled in the art, however, that these concepts may be practiced without these specific details. In some instances, well-known structures and components are shown in block diagram form in order to avoid obscuring such concepts.

As used herein, the terms “processor” and “controller” are used to describe elements that perform a function, an operation, or a sequence of operations. The function, operation, or sequence of operations can be hard coded into an electronic circuit or soft coded by way of instructions held in a memory device. The function, operation, or sequence of operations can be performed using digital values or using analog signals. In some embodiments, the processor or controller can be embodied in an application specific integrated circuit (ASIC), which can be an analog ASIC or a digital ASIC, in a microprocessor with associated program memory, in a discrete electronic circuit which can be analog or digital, and/or in special purpose logic circuitry (e.g., a field programmable gate array (FPGA)). Processing can be implemented in hardware, software, or a combination of the two. Processing can be implemented using computer programs executed on programmable computers/machines that include one or more processors, a storage medium or other article of manufacture that is readable by the processor (including volatile and non-volatile memory and/or storage elements), at least one input device and one or more output devices. Program code can be applied to data entered using an input device to perform processing and to generate output information. A processor or controller can contain internal processors or modules that perform portions of the function, operation, or sequence of operations. Similarly, a module can contain internal processors or internal modules that perform portions of the function, operation, or sequence of operations of the module.

While electronic circuits shown in figures herein may be shown in the form of analog blocks or digital blocks, it will be understood that the analog blocks can be replaced by digital blocks that perform the same or similar functions and the digital blocks can be replaced by analog blocks that perform the same or similar functions. Analog-to-digital or digital-to-analog conversions may not be explicitly shown in the figures but should be understood.

As used herein, the term “magnetic field sensing element” is used to describe a variety of electronic elements that can sense a magnetic field. The magnetic field sensing element can be, but is not limited to, a Hall effect element, a magnetoresistance element, a magnetotransistor, or an inductive coil. As is known, there are different types of Hall effect elements, for example, a planar Hall element, a vertical Hall element, and a Circular Vertical Hall (CVH) element. As is also known, there are different types of magnetoresistance elements, for example, a semiconductor magnetoresistance element such as Indium Antimonide (InSb), a giant magnetoresistance (GMR) element, for example, a spin valve, an anisotropic magnetoresistance element (AMR), a tunneling magnetoresistance (TMR) element, and a magnetic tunnel junction (MTJ). The magnetic field sensing element may be a single element or, alternatively, may include two or more magnetic field sensing elements arranged in various configurations, e.g., a half bridge or full (Wheatstone) bridge. Depending on the device type and other application requirements, the magnetic field sensing element may be a device made of a type IV semiconductor material such as Silicon (Si) or Germanium (Ge), or a type III-V semiconductor material like Gallium-Arsenide (GaAs) or an Indium compound, e.g., Indium-Antimonide (InSb).

As is known, some of the above-described magnetic field sensing elements tend to have an axis of maximum sensitivity parallel to a substrate or in the plane of the substrate that supports the magnetic field sensing element, and others of the above-described magnetic field sensing elements tend to have an axis of maximum sensitivity perpendicular to a substrate that supports the magnetic field sensing element. In particular, planar Hall elements tend to have axes of maximum sensitivity perpendicular to a substrate, while metal based or metallic magnetoresistance elements (e.g., GMR, TMR, AMR) and vertical Hall elements tend to have axes of maximum sensitivity parallel to a substrate.

As used herein, the term “magnetic field signal” is used to describe any signal that results from a magnetic field experienced by a magnetic field sensing element.

It is noted that various connections and positional relationships (e.g., over, below, adjacent, etc.) may be used to describe elements and components in the description and drawings. These connections and/or positional relationships, unless specified otherwise, can be direct or indirect, and the described concepts, systems, devices, structures, and techniques are not intended to be limiting in this respect. Accordingly, a coupling of entities can refer to either a direct or an indirect coupling, and a positional relationship between entities can be a direct or indirect positional relationship.

Also, the following definitions and abbreviations are to be used for the interpretation of the claims and the specification. The terms “comprise,” “comprises,” “comprising, “include,” “includes,” “including,” “has,” “having,” “contains” or “containing,” or any other variation are intended to cover a non-exclusive inclusion. For example, an apparatus, a method, a composition, a mixture, or an article, that includes a list of elements is not necessarily limited to only those elements but can include other elements not expressly listed or inherent to such apparatus, method, composition, mixture, or article.

References in the specification to “embodiments,” “one embodiment, “an embodiment,” “an example embodiment,” “an example,” “an instance,” “an aspect,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it may affect such feature, structure, or characteristic in other embodiments whether explicitly described or not.

Use of ordinal terms such as “first,” “second,” “third,” etc., in the claims to modify a claim element does not by itself connote any priority, precedence, or order of one claim element over another, or a temporal order in which acts of a method are performed, but are used merely as labels to distinguish one claim element having a certain name from another element having a same name (but for use of the ordinal term) to distinguish the claim elements.

In the foregoing detailed description, various features of embodiments are grouped together in one or more individual embodiments for the purpose of streamlining the disclosure. This method of disclosure is not to be interpreted as reflecting an intention that the claims require more features than are expressly recited therein. Rather, inventive aspects may lie in less than all features of each disclosed embodiment.

Elements of different embodiments described herein may be combined to form other embodiments not specifically set forth above. Various elements, which are described in the context of a single embodiment, may also be provided separately or in any suitable subcombination. Other embodiments not specifically described herein are also within the scope of the following claims.

Having described implementations which serve to illustrate various concepts, structures, and techniques which are the subject of this disclosure, it will now become apparent to those of ordinary skill in the art that other implementations incorporating these concepts, structures, and techniques may be used. Accordingly, it is submitted that that scope of the patent should not be limited to the described implementations but rather should be limited only by the spirit and scope of the following claims.

What is claimed is:

1. A current sensor integrated circuit (IC) package comprising:
a lead frame comprising a primary conductor and signal leads, the lead frame having a lead frame surface;
a semiconductor die having a die surface adjacent to the lead frame surface, the semiconductor die comprising a magnetic field sensing element supported by the semiconductor die, wherein the magnetic field sensing element is configured to sense a magnetic field associated with a current through the primary conductor and generate an output signal indicative of the current; and
a conductive film located between the die surface of the semiconductor die and at least one signal lead, wherein the conductive film is conductive in a first direction extending from the die surface to the at least one signal lead and nonconductive in a second direction which is perpendicular to the first direction.

2. The current sensor IC package of claim 1 wherein the conductive film comprises an anisotropic conductive film (ACF).

3. The current sensor IC package of claim 1 wherein the semiconductor die is bonded to the lead frame in a flip-chip arrangement.

4. The current sensor IC package of claim 1 wherein the conductive film is configured to prevent a tilt of the semiconductor die relative to the lead frame.

5. The current sensor IC package of claim 1 further comprising an insulation structure between the semiconductor die and the primary conductor.

6. The current sensor IC package of claim 5 wherein the conductive film has a thickness substantially equal to an insulation thickness of the insulation structure.

7. The current sensor IC package of claim 5 wherein the insulation structure includes a polymer film.

8. The current sensor IC package of claim 1 wherein the conductive film is configured to control a gap height between the semiconductor die and the lead frame.

9. The current sensor IC package of claim 1 wherein the semiconductor die includes one or more bumps coupling the semiconductor die to the conductive film.

10. The current sensor IC package of claim 9 wherein the one or more bumps include copper bumps.

11. The current sensor IC package of claim 1 further comprising a molding encapsulating the semiconductor die and at least a portion of the lead frame.

12. The current sensor IC package of claim 1 wherein the first direction is orthogonal to the die surface.

13. A method of manufacturing a current sensor integrated circuit (IC) package, the method comprising:
providing a lead frame comprising a primary conductor and signal leads, the lead frame having a lead frame surface;
positioning a semiconductor die having a die surface adjacent to the lead frame surface, the semiconductor die comprising a magnetic field sensing element supported by the semiconductor die, wherein the magnetic field sensing element is configured to sense a magnetic field associated with a current through the primary conductor and generate an output signal indicative of the current; and
positioning a conductive film between the die surface of the semiconductor die and at least one signal lead, wherein the conductive film is conductive in a first direction extending from the die surface to the at least one signal lead and nonconductive in a second direction which is perpendicular to the first direction.

14. The method of claim 13 wherein the conductive film comprises an anisotropic conductive film (ACF).

15. The method of claim 13 wherein the semiconductor die is bonded to the lead frame in a flip-chip arrangement.

16. The method of claim 13 wherein the conductive film is configured to prevent a tilt of the semiconductor die relative to the lead frame.

17. The method of claim 13 further comprising positioning an insulation structure between the semiconductor die and the primary conductor.

18. The method of claim 17 wherein the conductive film has a thickness substantially equal to an insulation thickness of the insulation structure.

19. The method of claim 17 wherein the insulation structure includes a polymer film.

20. The method of claim 13 wherein the conductive film is configured to control a gap height between the semiconductor die and the lead frame.

21. The method of claim 13 wherein the semiconductor die includes one or more bumps coupling the semiconductor die to the conductive film.

22. The method of claim 21 wherein the one or more bumps include copper bumps.

23. The method of claim 13 further comprising encapsulating the semiconductor die and at least a portion of the lead frame with a molding.

24. The method of claim 13 wherein the first direction is orthogonal to the die surface.

25. The method of claim 13 further comprising mounting the conductive film to the semiconductor die prior to positioning the conductive film between the die surface of the semiconductor die and the at least one signal lead.

26. The method of claim 13 further comprising mounting conductive film to the lead frame prior to positioning the conductive film between the die surface of the semiconductor die and the at least one signal lead.

27. The method of claim 13 wherein the conductive film is mounted to one or the lead frame or the semiconductor die with compressed heating.

28. A current sensor integrated circuit (IC) package comprising:
a lead frame comprising a primary conductor and signal leads, the lead frame having a lead frame surface;
a semiconductor die having a die surface adjacent to the lead frame surface, the semiconductor die comprising a magnetic field sensing element supported by the semiconductor die, wherein the magnetic field sensing element is configured to sense a magnetic field associated with a current through the primary conductor and generate an output signal indicative of the current; and
an anisotropic conductive film heat-pressed to one or both of the die surface and at least one signal lead, wherein the anisotropic conductive film is conductive in a first direction extending from the die surface to the at least one signal lead and nonconductive in a second direction which is perpendicular to the first direction and further wherein the anisotropic conductive film is configured to control a gap height between the semiconductor die and the at least one signal lead.
